(19) United States
(12) Patent Application Publication
(10) Pub. No.: US 2026/0178809 A1
(43) Pub. Date: Jun. 25, 2026

(54) ANALOG CIRCUIT FLOATING GATE ANALYSIS

(71) Applicant: TEXAS INSTRUMENTS INCORPORATED, Dallas, TX (US)

(72) Inventors: Jose Fresquez, Murphy, TX (US); Md Noor E Elahi, Allen, TX (US); Jian Chang, Plano, TX (US); Stephan Endrass, Freising (DE)

(21) Appl. No.: 18/988,414

(22) Filed: Dec. 19, 2024

(51) Int. Cl. G06F 30/3323; G06F 30/323

(52) U.S. Cl. CPC G06F 30/3323; G06F 30/323

(57) ABSTRACT

Various embodiments of the present disclosure relate to the detection of floating gates within analog circuits via analog circuit analysis. In one example embodiment, a technique for performing analog circuit analysis is provided. The technique first includes generating a netlist for each device gate of an analog circuit, such that generating the netlist includes determining a type and a directionality of each device gate of the analog circuit. Next the technique includes generating a circuit model for the analog circuit based on the netlist. Once generated, the technique includes supplying the circuit model and the netlist as input to an analysis engine configured to perform analog circuit analysis. For example, the analysis engine may be configured to execute a formal verification process by outputting a warning for when a floating gate is detected within the circuit model.

### TECHNICAL FIELD

Aspects of the disclosure are related to the field of computing hardware and software, and more particularly, to analog circuit analysis.

### BACKGROUND

Analog circuit analysis is representative of a technique for observing the behavior of analog/mixed-signal circuits when subjected to various conditions. For example, analog circuit analysis may be utilized to determine which conditions, if any, cause the device gates of a circuit to represent floating gates. A device gate is representative of a control terminal which modulates the flow of current within a transistor by forcing the device gate to a known voltage, while a floating gate is representative of a device gate which is not being forced to a known voltage. Meaning that, the voltage of a floating gate can take any value. Problematically, floating gates can introduce a variety of issues to the circuit. For example, floating gates may introduce current leakage, thereby leading to increased power consumption, data corruption, and other issues of the like within the circuit.

Currently, various techniques exist for performing analog circuit analysis, including dynamic analysis methods and static analysis methods. Dynamic analysis methods generate a transient simulation of the circuit and subject the transient simulation to various conditions, such that each power mode of the circuit is tested under the various conditions. Problematically, analog/mixed-signal circuits typically include multiple power modes, and testing each power mode via the current dynamic analysis methods takes too long to be useful. Meaning that the current dynamic analysis methods are non-exhaustive.

Alternatively, static analysis methods test the various connections within the circuit to ensure all the elements of the circuit are in the correct configuration. Problematically, current static analysis methods fail to consider the various power modes of the circuit, as only the steady-state power mode of the circuit may be tested statically. In addition, current static analysis methods are prone to output false detections. Meaning that current static analysis methods are unreliable.

In contrast, various techniques also exist for performing digital circuit analysis. Unfortunately, such techniques fail to provide an outlet for testing the functionality of analog/mixed-signal circuits. For example, current methods for testing digital circuits may employ a formal verification process, where a model of a digital circuit is generated and provided as input to an analysis engine configured to detect floating gates via the formal verification process. Problematically, no methods currently exist for generating a model of an analog/mixed-signal circuit which fits the criterion of the formal verification process.

### SUMMARY

Disclosed herein is technology, including systems, methods, and devices for performing analog circuit analysis. Analog circuit analysis describes a technique for detecting floating gates within the analog elements of a circuit. In various implementations, a technique for performing analog circuit analysis is provided. In one example embodiment, the technique first includes generating a netlist for the one or more device gates of an analog circuit, such that the netlist is representative of a text description of the analog circuit.

In an implementation, to generate the netlist, the technique first includes, for each device gate of the analog circuit, determining a type for the device gate. For example, the technique may include determining whether the type of each device gate is representative of a p-channel metal-oxide-semiconductor (PMOS) or an n-type metal-oxide-semiconductor (NMOS). Next, to generate the netlist, the technique further includes, for each device gate of the analog circuit, determining a directionality for the device gate based on the logical positions of the source terminal and the drain terminal of the device gate. For example, the technique may include determining whether the directionality of each device gate is representative of a unidirectional model or a bidirectional model.

Next, the technique includes generating a circuit model for the analog circuit based on the netlist, such that the circuit model is a binary encoded representation of the analog circuit. Once generated, the technique includes providing the circuit model and the netlist as input to an analysis engine which is configured to perform analog circuit floating gate analysis. For example, the analysis engine may be representative of circuitry configured to execute a formal verification process with respect to the circuit model and the netlist. In an implementation, to execute the formal verification process, the analysis engine is configured to test the circuit model under all possible conditions and output a warning when a floating gate is detected within the circuit model.

This Summary is provided to introduce a selection of concepts in a simplified form that are further described below in the Detailed Description. It may be understood that this Summary is not intended to identify key features or essential features of the claimed subject matter, nor is it intended to be used to limit the scope of the claimed subject matter.

### BRIEF DESCRIPTION OF THE DRAWINGS

Many aspects of the disclosure may be better understood with reference to the following drawings. The components in the drawings are not necessarily to scale, emphasis instead being placed upon clearly illustrating the principles of the present disclosure. Moreover, in the drawings, like reference numerals designate corresponding parts throughout the several views. While several embodiments are described in connection with these drawings, the disclosure is not limited to the embodiments disclosed herein. On the contrary, the intent is to cover all alternatives, modification's, and equivalents.

FIG. 1 illustrates an operational environment in an implementation.

FIG. 2 illustrates a circuit analysis method in an implementation.

FIG. 3 illustrates another operational environment in an implementation.

FIG. 4 illustrates an analog circuit in an implementation.

FIGS. 5A-5B illustrate device models in an implementation.

FIG. 6 illustrates a table in an implementation.

FIGS. 7A & 7B illustrate an operational scenario in an implementation.

FIG. 8 illustrates another circuit analysis method in an implementation.

FIG. 9 illustrates another circuit analysis method in an implementation.

FIG. 10 illustrates another table in an implementation.

FIG. 11 illustrates a results table in an implementation.

FIG. 12 illustrates a computing system suitable for implementing the various operational environments, architectures, processes, scenarios, and sequences discussed below with respect to the other Figures.

### DETAILED DESCRIPTION

Technology is disclosed herein for performing analog circuit analysis within the context of analog and mixed-signal circuits. Analog circuit analysis is representative of a technique for testing the behavior of the analog elements of a circuit when subjected to different conditions. For example, analog circuit analysis may be utilized to determine which conditions allow for the device gates of a circuit to be representative of floating gates.

A device gate is representative of a control terminal which modulates the flow of current within an associated transistor (e.g., PMOS or NMOS) by forcing the device gate to known voltages. Accordingly, device gates are representative of circuit elements which manage the flow of current throughout the circuit. In contrast, a floating gate is representative of a device gate which has been forced to an unknown voltage, which may lead to a variety of downstream effects that degrade the performance of the circuit. For example, floating gates can introduce current leakage into a circuit, which may lead to data corruption, increased power consumption, signal degradation, unwanted biasing, and other issues of the like.

Existing techniques for performing analog circuit analysis are non-exhaustive and unreliable. For example, dynamic analysis methods generate a transient simulation of the circuit, and test the simulation under various conditions, such that each power mode of the circuit is tested under the various conditions. Problematically, current dynamic analysis methods are non-exhaustive as analog/mixed-signal circuits typically comprise multiple power modes, and testing each power mode via the current dynamic analysis methods takes too long to be useful. In addition, current dynamic analysis methods are user stimulus driven, such that the current techniques require a user to provide test cases for testing the transient simulation under the various conditions. Consequently, a user must have a complete understanding of the circuit to provide stimulus which triggers floating gates.

Alternatively, static analysis methods test the various connections within the circuit to ensure the elements are properly configured. Problematically, current static analysis methods are unreliable as these methods are prone to output false detections. In addition, because the circuit is tested statically, current static analysis methods are only able to test the steady-state power mode of the circuit, and as a result, are unable to identify propagated floating gates. Meaning that, current static analysis methods are unable to determine if a first floating gate leads to additional floating gates within the circuit. In contrast, disclosed herein is a new technique for performing analog circuit analysis which leverages digital circuit analysis techniques, and by design, provides a more reliable and exhaustive technique for performing analog circuit analysis which does not require a complete understanding of the circuit.

In one example embodiment a technique for performing analog circuit analysis is provided. The technique may be employed by processing circuitry to cause the processing circuitry to detect floating gates within the analog elements of analog/mixed-signal circuits. For example, the technique may cause the processing circuitry to test an exhaustive amount of stimulus to determine which conditions cause the device gates of a circuit to be representative of floating gates.

In an implementation, the technique first causes the processing circuitry to generate a netlist for the device gates of a circuit. The netlist is representative of a text description which describes or characterizes the components within the circuit, and the connections between said components. For example, the netlist may be representative of a SystemVerilog description of the circuit. In an implementation, to generate the netlist, the technique causes the processing circuitry to analyze the circuit to determine a type for each device gate of the circuit. For example, the technique may cause the processing circuitry to determine if the type of each device gate is representative of a PMOS or an NMOS. Next, to generate the netlist, the technique causes the processing circuitry to determine a directionality (e.g., polarity) for each device gate of the circuit. For example, the technique may cause the processing circuitry to determine if the directionality of each device gate is representative of a unidirectional model or a bidirectional model based on the logical positions of the source and drain terminals of each device gate.

Next, the technique causes the processing circuitry to generate a circuit model for the circuit based on or using the netlist. Additionally or alternatively, the technique may include generating the netlist and the circuit model in parallel. Once generated, the technique causes the processing circuitry to perform analog circuit analysis with respect to the netlist and the circuit model. For example, the processing circuitry may be configured to execute a formal verification process with respect to the netlist and the circuit model.

The formal verification process is representative of a technique which was designed to test the behavior of digital circuits under all possible conditions. More specifically, the formal verification process is representative of a mathematical approach which ensures the elements of a circuit adhere to their associated design specifications. As such, the formal verification process may be employed within the context of analog circuit analysis to provide an exhaustive approach for detecting floating gates. For example, the processing circuitry may be configured to execute the formal verification process with respect to the circuit model and the netlist to determine which conditions cause the device gates of the circuit to be representative of floating gates. In an implementation, during the formal verification process, the processing circuitry is configured to output a warning when a floating gate is detected. For example, the processing circuitry may provide a warning that indicates which conditions caused a floating gate in the circuit.

Advantageously, the proposed technology provides an exhaustive technique for performing analog circuit analysis. As a result, the proposed technology provides a more reliable approach for detecting floating gates within analog and mixed-signal circuits which does not require a user to provide stimulus for testing the circuit. Furthermore, the proposed technology provides a method for mitigating current leakage within analog/mixed-signal circuits, thereby resulting in cost savings for the manufacturers/customers for when the circuit is deployed.

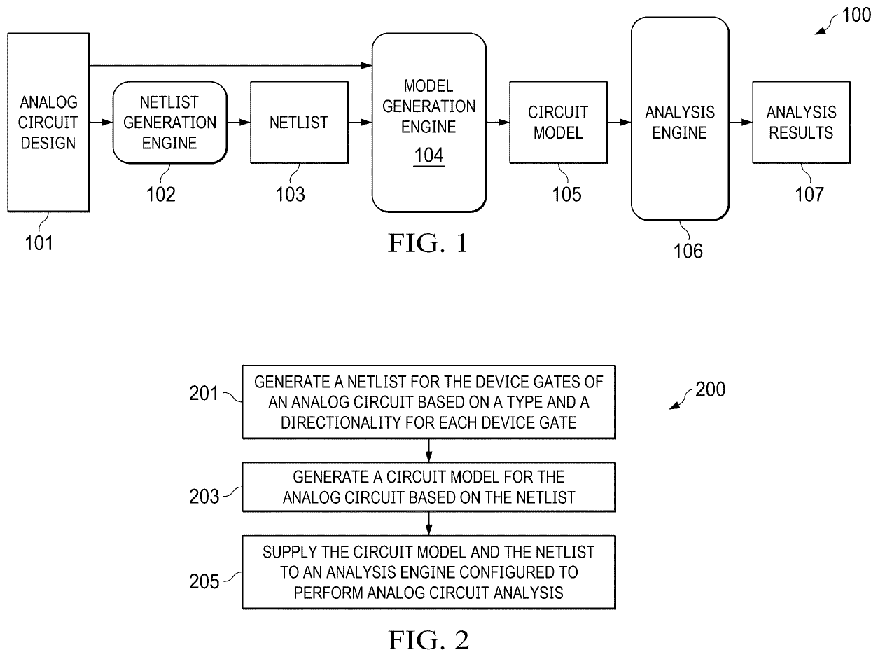

Now turning to the figures, FIG. 1 illustrates operating environment 100 in an implementation. Operating environment 100 is representative of an example environment configurable to perform analog circuit analysis. For example, operating environment 100 may be configured to detect floating gates within analog or mixed-signal circuits. For the purposes of explanation, analog circuits will be discussed herein. This specification is not meant to limit the applications of the proposed technology, but rather to provide an example. Operating environment 100 includes analog circuit design 101, netlist generation engine 102, netlist 103, model generation engine 104, circuit model 105, analysis engine 106, and analysis results 107.

Analog circuit design 101 is representative of an analog circuit. For example, analog circuit design 101 may represent a computer aided design (CAD) model. In an implementation, analog circuit design 101 is generated by processing circuitry configured to execute the analog circuit analysis. For example, processing circuitry associated with operating environment 100 may be configured to analyze an analog circuit to generate analog circuit design 101 and provide analog circuit design 101 as input to netlist generation engine 102 and model generation engine 104.

Netlist generation engine 102 is representative of software, hardware, firmware, or a combination thereof configured to generate a netlist for the device gates of an analog circuit. A netlist is representative of a text description of the analog circuit, such that the netlist describes the components in the circuit as well as the various connections among the components. For example, the netlist may be representative of a SystemVerilog description which lists the resistors, capacitors, and transistors captured within analog circuit design 101.

In an implementation, to generate the netlist for analog circuit design 101, netlist generation engine 102 is configured to determine the device type and device directionality of each device gate within the analog circuit. For example, netlist generation engine 102 may analyze analog circuit design 101 to determine if the type of each device gate is representative of a PMOS or an NMOS. Netlist generation engine 102 may be configured to produce netlist 103 with contents that are different from netlists generated using existing methods. Each element and instance (e.g., transistor connection) in netlist 103 may be model uniquely or differently, as compared to existing netlists.

Once determined, netlist generation engine 102 may further analyze analog circuit design 101 to identify the locations of the source and drain terminals of each device gate to determine if the directionality of the device gates is representative of a unidirectional model or a bidirectional model. A unidirectional model describes the directionality for when the source terminal or the drain terminal of a device gate is connected to an input node or an output node of the circuit. Alternatively, a bidirectional model describes the directionality for when neither the source terminal nor the drain terminal of a device gate is connected to an input node or an output node of the circuit.

In an implementation, after determining the directionality of each device gate represented by analog circuit design 101, netlist generation engine 102 is configured to output netlist 103. Netlist 103 is representative of the text description (e.g., SystemVerilog description) of analog circuit design 101, such that netlist 103 lists the type and directionality of each device gate within analog circuit design 101, and further lists the components of analog circuit design 101, and the connections between said components. In an implementation, netlist 103 is provided as input to model generation engine 104.

Model generation engine 104 is representative of software, hardware, firmware, or a combination thereof configured to generate a circuit model for the analog circuit, such that the circuit model may be supplied as input to circuitry which is configured to perform digital circuit analysis. For example, model generation engine 104 may be configured to generate circuit model 105 based on or using analog circuit design 101 and netlist 103, such that circuit model 105 is representative of a model (e.g., binary encoded representation) which may be supplied as input to circuitry which is configured to execute a formal verification process with respect to circuit model 105. In an implementation, model generation engine 104 provides circuit model 105 as input to analysis engine 106. Alternatively, model generation engine 104 may be configured to generate circuit model 105 using analog circuit design 101, in parallel with netlist generation engine 102 generating netlist 103.

Analysis engine 106 is representative of software, hardware, firmware, or a combination thereof configured to perform circuit analysis. More specifically, analysis engine 106 is representative of an engine which is configured to perform digital circuit analysis with respect to an analog circuit. For example, analysis engine 106 may be representative of circuitry configured to perform a formal verification process with respect to circuit model 105.

The formal verification process is representative of a digital circuit analysis technique which utilizes mathematical algorithms to ensure the components of a circuit behave as expected under all possible conditions. In an implementation, analysis engine 106 receives circuit model 105 from model generation engine 104, and in response, executes the formal verification process with respect to circuit model 105. Output of analysis engine 106 is represented by analysis results 107. In some examples, analysis engine 106 performs direct-current (DC) analysis of netlist 103 and/or circuit model 105. In such examples, analysis engine 106 can abstract out the passive components in netlist 103 and/or circuit model 105 to DC elements in the circuit before performing the DC analysis.

Analysis results 107 are representative of results of the formal verification process. For example, analysis results 107 may provide an indication on what conditions caused floating gates within circuit model 105. Analysis results 107 may further provide an indication on other issues identified within circuit model 105. In an implementation, analysis results 107 are utilized to update the associated analog circuit, such that the analog circuit is updated to minimize the possibility of issues within the circuit. For example, the analog circuit may be updated to mitigate the chances of floating gates for when the circuit is deployed. Analysis engine 106 may be capable of finding each combination of circuit inputs that results in a floating gate within the circuit model 105. Analysis engine 106 may then analyze and report the floating gate(s) and the downstream effects (e.g., leakage current) of the floating gate(s) within circuit model 105.

In an implementation, netlist generation engine 102, model generation engine 104, and analysis engine 106 are executed by processing circuitry configured to identify issues (e.g., floating gates) within the analog elements of analog/mixed-signal circuits. In another implementation, netlist generation engine 102, model generation engine 104, and analysis engine 106 are executed across multiple processing cores configured to identify issues (e.g., floating gates) within the analog elements of analog/mixed-signal circuits.

FIG. 2 illustrates analysis method 200 in an implementation. Analysis method 200 is representative of software for performing circuit analysis with respect to an analog or mixed-signal circuit, but for the purposes of brevity, analog circuits will be discussed herein. This is not meant to limit the applications of analysis method 200, but rather to provide an example. Analysis method 200 may be implemented in the context of program instructions that, when executed by a suitable computing system, direct the processing circuitry of the computing system to operate as follows, referring parenthetically to the steps in FIG. 2. For the purposes of explanation, analysis method 200 will be explained with the elements of FIG. 1. This is not meant to limit the applications of analysis method 200, but rather to provide an example.

To begin, analog circuit design 101 is provided as input to netlist generation engine 102 to cause netlist generation engine 102 to generate netlist 103 based on or using the type and the directionality of each device gate represented within analog circuit design 101 (step 201). In an implementation, to generate netlist 103, netlist generation engine 102 is configured to generate a list of all the components represented within analog circuit design 101 and map the connections between said components. Once generated, netlist generation engine 102 is configured to analyze the device gates represented within the list to determine the type and directionality of each device gate.

For example, netlist generation engine 102 may, for each device gate, determine whether a device gate is representative of an NMOS or a PMOS. Once determined, netlist generation engine 102 may, for each device gate, determine whether the directionality of a device gate is representative of a unidirectional model, or a bidirectional model. A unidirectional model is representative of a device gate where either the source terminal or the drain terminal of the device gate is connected to an input node or an output node of the circuit. Alternatively, a bidirectional model is representative of a device gate where neither the source terminal nor the drain terminal of the device gate is connected to an input node or an output node of the circuit.

In an implementation, if netlist generation engine 102 determines that the source terminal of a device gate is connected to an input node or determines that the drain terminal of the device gate is connected to an output node, then netlist generation engine 102 is configured to classify the directionality of the device gate as a unidirectional model. Alternatively, if netlist generation engine 102 determines that the source terminal of a device gate is connected to an output node or determines that the drain terminal of the device gate is connected to an input node, then netlist generation engine 102 is configured to switch the polarity of the device gate and classify the directionality of the device gate as a unidirectional model. Meaning that, netlist generation engine 102 is configured to cause the drain terminal of the device gate to be connected to the output node (rather than the source terminal being connected to the output node) or cause the source terminal of the device gate to be connected to the input node (rather than the drain terminal being connected to the input node).

In contrast, if netlist generation engine 102 determines that neither the source terminal nor the drain terminal of a device gate is connected to an input node or an output node of the analog circuit, then netlist generation engine 102 may classify the device gate as a bidirectional model. For example, netlist generation engine 102 may determine that the source terminal of the device gate is connected to a resistor which is not directly connected to an input node or an output node of the analog circuit. In addition, netlist generation engine 102 may determine that the drain terminal of the device gate is connected to a resistor which is not directly connected to an input node or an output node of the analog circuit. It should be noted that, if netlist generation engine 102 determines that either the source terminal or the drain terminal of a device gate is connected to a resistor (or another element of the like) which is directly connected to an input node or an output node of the analog circuit, then netlist generation engine 102 is configured to classify the directionality of the device gate as a unidirectional model.

Next, netlist generation engine 102 supplies netlist 103 to model generation engine 104 to cause model generation engine 104 to generate circuit model 105 (step 203). Circuit model 105 is representative of a digital model of analog circuit design 101, such that circuit model 105 may be supplied to circuitry configured to leverage digital circuit analysis techniques for performing analog circuit analysis. For example, circuit model 105, and netlist 103, may be supplied to analysis engine 106 to cause analysis engine 106 to execute a formal verification process with respect to circuit model 105 and netlist 103 (step 205). The formal verification process is representative of an exhaustive analysis approach which tests circuit model 105 under all possible conditions via mathematical proofs to determine the conditions which cause issues within the circuit elements (e.g., transistors, capacitors, resistors etc.) of circuit model 105. A formal verification process may involve a digital logic checker crawling the netlist 103 to check for issues in the circuit model 105.

In an implementation, after executing the formal verification process, analysis engine 106 is configured to output analysis results 107. Analysis results 107 are representative of results which indicate the conditions that caused issues within circuit model 105, and in turn, the analog circuit. For example, analysis results 107 may indicate the conditions which caused floating gates within circuit model 105. In addition, analysis results 107 may indicate the conditions which caused issues within the other circuit elements of circuit model 105. In an implementation, analysis results 107 are utilized to modify the analog circuit to mitigate the chances of issues, such as floating gates, for when the circuit is deployed.

Advantageously, analysis method 200 provides a technique for performing analog circuit floating gate analysis which leverages digital analysis methodologies for detecting floating gates within analog and mixed-signal circuits. As a result, analysis method 200 is representative of an exhaustive approach for detecting floating gates, and by design, is more reliable at identifying the conditions which cause floating gates. Furthermore, analysis method 200 provides a technique which reduces current leakage, thereby mitigating the downstream effects caused by floating gates (e.g., data corruption, increased power consumption, or signal degradation).

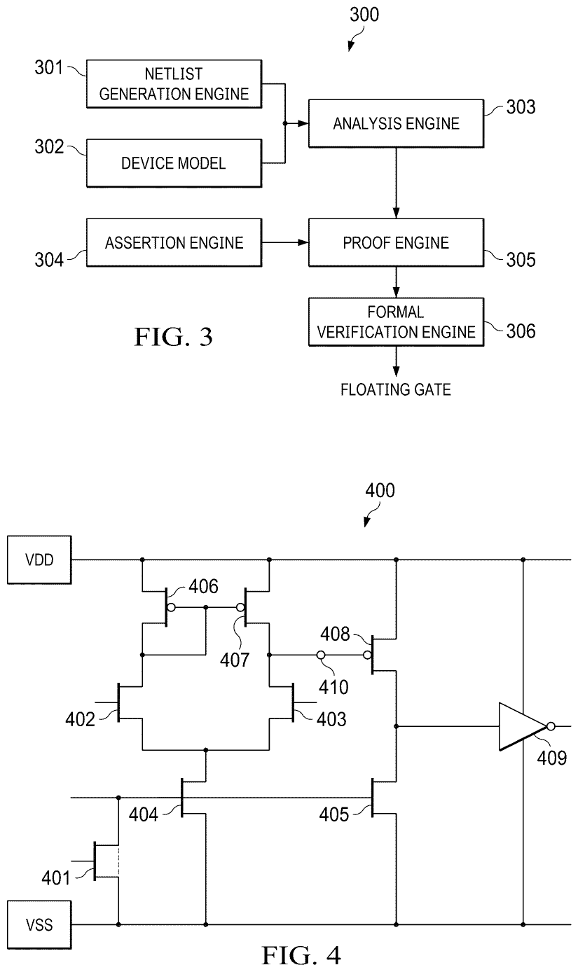

FIG. 3 illustrates operating environment 300 in an implementation. Operating environment 300 is representative of another example environment configurable to perform analog circuit analysis. For example, operating environment 300 may be representative of operating environment 100 of FIG. 1. Operating environment 300 includes netlist generation engine 301, device model 302, analysis engine 303, assertion engine 304, proof engine 305, and formal verification engine 306.

Netlist generation engine 301 is representative of software, hardware, firmware, or a combination thereof configured to generate a netlist for the device gates of an analog circuit. For example, netlist generation engine 301 may be representative of netlist generation engine 102 of FIG. 1. Input to netlist generation engine 301 includes an analog circuit model, while the output includes a netlist for the circuit model. For example, input to netlist generation engine 301 may include a CAD model of an analog circuit (e.g., analog circuit design 101), while the output includes a netlist which lists the components within the CAD model, the connections between the components within the CAD model, the type of device gates within the CAD model, and the directionality of the device gates within the CAD model.

In an implementation, to generate the netlist, netlist generation engine 301 analyzes the provided analog circuit model to determine the type and directionality of each device gate within the circuit model. For example, netlist generation engine 301 may determine whether each device gate is representative of an NMOS or a PMOS. Once determined, netlist generation engine 301 may determine whether the directionality of each device gate is representative of a unidirectional model, or a bidirectional model based on the locations of the source terminal and the drain terminal of each device gate.

If netlist generation engine 301 determines that the source terminal of a device gate is connected directly or indirectly to an input node of the circuit, then netlist generation engine 301 is configured to classify the directionality of the device gate as a unidirectional model. Alternatively, if netlist generation engine 301 determines that the source terminal of a device gate is connected directly or indirectly to an output node of the circuit, then netlist generation engine 301 is configured to reverse the polarity of the device gate and classify the directionality of the device gate as a unidirectional model.

If netlist generation engine 301 determines that the drain terminal of a device gate is connected directly or indirectly to an output node of the circuit, then netlist generation engine 301 is configured to classify the directionality of the device gate as a unidirectional model. Alternatively, if netlist generation engine 301 determines that the drain terminal of a device gate is connected directly or indirectly to an input node of the circuit, then netlist generation engine 301 is configured to reverse the polarity of the device gate and classify the directionality of the device gate as a unidirectional model. It should be noted that, an indirect connection to an input node or an output node is representative of when a terminal of a device gate is connected to a circuit element (e.g., resistor), which is directly connected to the input node or output node of the circuit.

Alternatively, if netlist generation engine 301 determines that neither the source terminal nor the drain terminal of a device gate is connected directly or indirectly to an input node or an output node of the circuit, then netlist generation engine 301 may classify the device gate as a bidirectional model. In an implementation, after determining the type and directionality of each device gate within the analog circuit model, netlist generation engine 301 is configured to provide the generated netlist as input to analysis engine 303. For example, input to analysis engine 303 may include a netlist from netlist generation engine 301 and device model 302.

Device model 302 is representative of a digital circuit model which depicts a circuit that requires analysis. For example, device model 302 may represent circuit model 105 of FIG. 1. In an implementation, device model 302 is representative of a model which may be supplied as input to circuitry configured to leverage digital circuit analysis techniques for detecting floating gates within analog/mixed-signal circuits. For example, device model 302 may be supplied to circuitry configured to perform a formal verification process. In an implementation, device model 302 is provided as input to analysis engine 303.

Analysis engine 303 is representative of software, hardware, firmware, or a combination thereof configured to determine if the generated netlist matches the specifications outlined by device model 302. For example, analysis engine 303 may receive device model 302 and the associated netlist, and in response, analyze the netlist to determine if the netlist accurately captures the components represented within device model 302. Output of analysis engine 303 is representative of an updated netlist which is provided as input to proof engine 305.

Proof engine 305 is representative of software, hardware, firmware, or a combination thereof configured to ensure that the updated netlist matches the specifications outlined by device model 302. In an implementation, proof engine 305 is further representative of an engine configured to add assertions to device model 302. For example, proof engine 305 may be configured to add assertions 304 to device model 302.

Assertions 304 are representative of targets which the components of device model 302 are expected to meet. For example, assertions 304 may designate the conditions which the device gates of device model 302 are expected to meet. In an implementation, assertions 304 are representative of high-impedance (high-z) assertions for the device gates of device model 302. A high-z assertion is representative of an assertion for identifying floating gate behaviors within device model 302. In an implementation, to add a high-z assertion to device model 302, proof engine 305 is configured to execute the following program code:
(1) foreach s [get_design_info-list signal-filter *.G-silent]{
(2) if{![regexp XDIG_TOP_I0 $s]}{
(3) if {[check_lib_cell $s]}{
(4) assert-name $s “@(posedge clk)##1 $s!==1’bz”}}}

Such that the program code causes proof engine 305 to identify each device gate within device model 302 and tag each device gate with a high-z assertion. Meaning that, the program code causes proof engine 305 to ensure that formal verification engine 306 is observing for when the device gates of device model 302 represent floating gates. In an implementation, after tagging the device gates with assertions 304, proof engine 305 is configured to execute the following program code:
(1) foreach s [get_property_list-include {status cex}]{
(2) visualize-violation-property $s-silent-bg-batch
(3) set i [get_property_info $s-list name]
(4) if {[lindex [visualize-get_value $i] end]==“1’bz”}{
(5) puts “FOUND FLOAT Z: $i”}
(6) visualize-clear_all}

Such that the program code causes proof engine 305 to instruct formal verification engine 306 to output a warning for when a floating gate is detected within device model 302. In an implementation, after inserting assertions 304 into device model 302, proof engine 305 is configured to provide the asserted device model to formal verification engine 306.

Formal verification engine 306 is representative of software, hardware, firmware, or a combination thereof configured to perform circuit analysis with respect to the asserted device model. For example, formal verification engine 306 may be representative of analysis engine 106 of FIG. 1. In an implementation, formal verification engine 306 is configured to utilize digital circuit analysis techniques to detect floating gates within the analog elements of analog/mixed-signal circuits. More specifically, formal verification engine 306 is configured to execute a formal verification process with respect to the asserted device model.

In an implementation, to perform the formal verification process, formal verification engine 306 is configured to execute a number of mathematical proofs to determine which conditions, if any, cause the device gates of the asserted device model to be representative of floating gates. Once determined, formal verification engine 306 is configured to output results which indicate the conditions that caused floating gates.

FIG. 4 illustrates analog circuit 400 in an implementation. Analog circuit 400 is representative of an exemplary circuit which requires analysis. For example, analog circuit 400 may be analyzed by circuitry configured to determine which conditions cause the device gates of analog circuit 400 to behave as floating gates (e.g., operating environment 100 or operating environment 300). Analog circuit 400 includes, but is not limited to, transistors 401, 402, 403, 404, 405, 406, 407, and 408, inverter 409, and node 410.

Transistors 401-408 are representative of a collection of NMOS and PMOS transistors, such that transistors 401-405 represent NMOS transistors and transistors 406-408 represent PMOS transistors. As such, transistors 401-408 each comprise a device gate, a source terminal, and a drain terminal. During operation, transistors 401-408 regulate the flow of current throughout analog circuit 400, thusly effecting the output of inverter 409.

Inverter 409 is representative of a circuit element which converts direct current into alternating current. More broadly, inverter 409 is representative of an exemplary circuit element which may be negatively affected by floating gates. As such, inverter 409 may be representative of any type of circuit element (e.g., capacitors, resistors, etc.), but for the purposes of explanation, inverter 409 will be discussed herein.

In an implementation, circuitry coupled to analog circuit 400 is configured to test analog circuit 400 under an exhaustive amount of stimulus to determine which conditions cause the device gates of transistors 401-408 to be representative of floating gates. For example, the circuitry may be configured to execute a formal verification process (e.g., analysis method 200) with respect to analog circuit 400. In an implementation to execute the formal verification process, the circuitry generates a netlist for analog circuit model 400 based on the type and directionality of each device gate. Next, the circuitry generates a circuit model of analog circuit 400 based on the netlist.

Once generated, the circuitry subjects the circuit model to an exhaustive amount of stimulus to determine which conditions cause the device gates of analog circuit 400 to be representative of floating gates. For example, the circuitry may apply various voltages to node 410 to determine the conditions which cause the device gate of transistor 408 to represent a floating gate, and in turn, determine the conditions which lead to propagated floating gates. As a result, the circuitry may determine which conditions induce current leakage, thereby negatively effecting inverter 409.

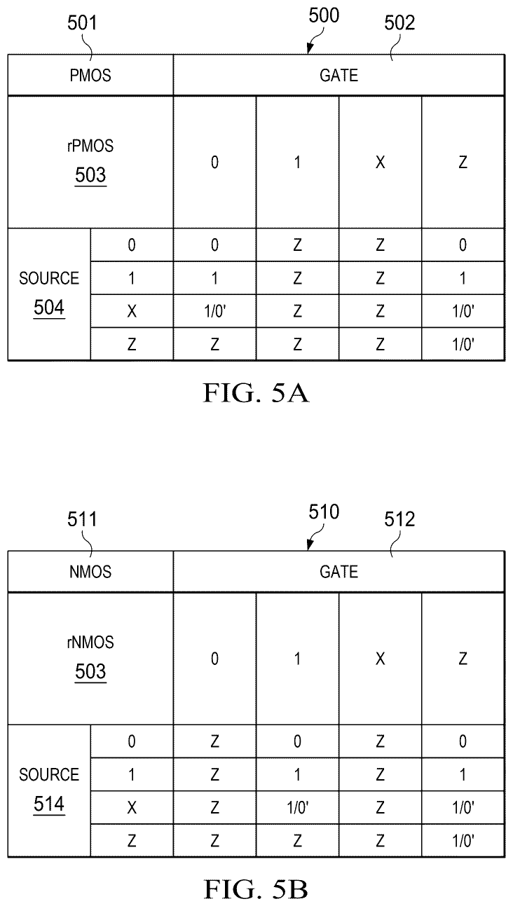

FIGS. 5A and 5B respectively illustrate device model 500 and device model 510 in an implementation. Device models 500 and 510 are representative of exemplary transistor models which define the ideal behavior for a transistor, such that device models 500 and 510 are representative of models which conform to SystemVerilog. Accordingly, device models 500 and 510 are representative of circuit models which may be supplied to circuitry (e.g., formal verification engine 306) configured to leverage digital circuit analysis techniques to perform analog/mixed-signal circuit analysis. Now turning to FIG. 5A, device model 500 is representative of a SystemVerilog PMOS model. Device model 500 includes PMOS column 501, gate column 502, resistive-PMOS (rPMOS) row 503, and source row 504.

PMOS column 501 is representative of a column which defines the transistor type for device model 500. Accordingly, device model 500 is representative of a device model which describes the ideal behavior for a PMOS. In an implementation, PMOS column 501 is populated to display a specific type of PMOS. For example, PMOS column 501 may be populated by rPMOS row 503.

rPMOS row 503 is representative of a row which defines the PMOS type for device model 500. Accordingly, device model 500 is specifically representative of a device model which describes the ideal behavior for an rPMOS. An rPMOS is representative of a type of PMOS which behaves as a resistor. As such, an rPMOS includes a device gate, source terminal, and drain terminal.

Gate column 502 is representative of a column which defines the various states for the device gate of an rPMOS. In an implementation, a device gate of a transistor, such as an rPMOS, may be represented within four different states including, off (i.e., 0), on (i.e., 1), unknown (i.e., X), and floating (i.e., Z). If the device gate of a transistor is off, then no current flows through the transistor. Alternatively, if the device gate of a transistor is on, then an expected amount of current flows through the transistor. If the device gate of a transistor is within an unknown state, then an unknown amount of current is flowing through the transistor. Finally, if the device gate of a transistor is floating, then the transistor is no longer capable of influencing the associated circuit. Meaning that, a floating device gate may introduce current leakage, and other downstream effects into the associated circuit.

Source row 504 is representative of a row which defines the various states for the source terminal of an rPMOS. In an implementation, the source terminal of a transistor (e.g., rPMOS), may be represented within four different states including, off (i.e., 0), on (i.e., 1), unknown (i.e., X), and floating (i.e., Z). If the source terminal of a transistor is off, then no current flows through the transistor. Alternatively, if the source terminal of a transistor is on, then an expected amount of current flows through the transistor. If the source terminal of a transistor is within an unknown state, then an unknown amount of current is flowing through the transistor. Finally, if the source terminal of a transistor is floating, then the transistor is no longer capable of influencing the associated circuit.

In an implementation, source row 504 depicts how the current state of the device gate affects the current state of the source terminal. For example, if the source terminal of an rPMOS is within an off state, and the associated device gate is in an off or floating state, then the source terminal remains in the off state. Alternatively, if the source terminal is in an off state, but the associated device gate is in an on or unknown state then the source terminal converts to the floating state.

Now turning to FIG. 5B, device model 510 is representative of a SystemVerilog NMOS model. Device model 510 includes NMOS column 511, gate column 512, resistive-NMOS (rNMOS) row 513, and source row 514.

NMOS column 511 is representative of a column which defines the transistor type for device model 510. Accordingly, device model 510 is representative of a device model which describes the ideal behavior for an NMOS. In an implementation, NMOS column 511 is populated to display a specific type of NMOS. For example, NMOS column 511 may be populated by rNMOS row 513.

rNMOS row 513 is representative of a row which defines the NMOS type for device model 510. Meaning that, device model 510 is specifically representative of a device model which describes the ideal behavior for an rNMOS. An rNMOS is representative of a type of NMOS which behaves as a resistor. As such, an rNMOS includes a device gate, source terminal, and drain terminal.

Gate column 512 is representative of a column which defines the various states for the device gate of an rNMOS. In an implementation, a device gate of a transistor, such as an rNMOS, may be represented within four different states including, off (i.e., 0), on (i.e., 1), unknown (i.e., X), and floating (i.e., Z). Alternatively, source row 514 is representative of a row which defines the various states for the source terminal of an rNMOS, such that the source terminal of a transistor (e.g., rNMOS), may be represented within four different states including, off (i.e., 0), on (i.e., 1), unknown (i.e., X), and floating (i.e., Z).

In an implementation, source row 514 depicts how the current state of the device gate affects the current state of the source terminal. For example, if the source terminal of an rNMOS is within an off state, but the associated device gate is in an off or unknown state, then the source terminal converts to a floating state. Alternatively, if the source terminal is in an off state, and the associated device gate is in an on or floating state then the source terminal remains in the off state.

In an implementation, circuitry which is configured to perform analog circuit analysis may generate a circuit model for an analog/mixed-signal circuit using device models 500 and 510. For example, model generation engine 104 may utilize device models 500 and 510 to generate circuit model 105.

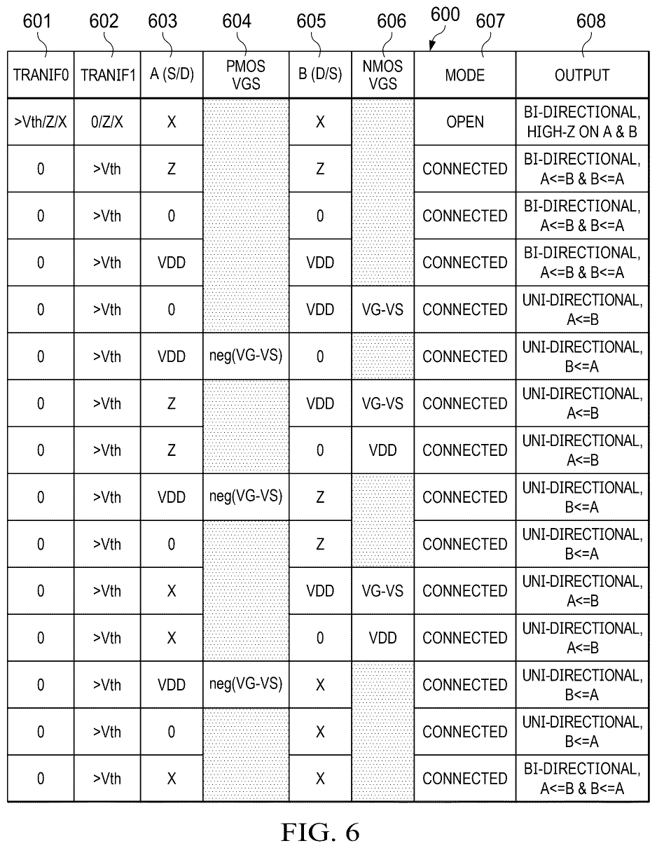

FIG. 6 illustrates table 600 in an implementation. Table 600 is representative of a table for determining the directionality of a device gate within an analog or mixed-signal circuit. For example, table 600 may be utilized by circuitry configured to generate a netlist by determining the type and the directionality of each device gate represented within a circuit. The directionality of a device gate describes the polarity of the device gate, such that the directionality of a device gate may be classified as a unidirectional model or a bidirectional model.

A unidirectional model is representative of a device gate where the source terminal or the drain terminal of the device gate is connected directly or indirectly to an input node or an output node of the circuit. Alternatively, a bidirectional model is representative of a device gate where neither the source terminal nor the drain terminal of the device gate is connected directly or indirectly to an input node or an output node of the circuit. Table 600 includes device gate column 601, device gate column 602, source terminal column 603, PMOS gate voltage column 604, drain terminal column 605, NMOS gate voltage column 606, mode column 607, and output column 608.

Device gate column 601 is representative of a column which defines the state for a device gate of an associated transistor, such that the state of a device gate describes the amount of current which is allowed to flow through the associated transistor. In an implementation, a device gate of a transistor may be represented within four different states including, off (i.e., 0), on (i.e., VDD), unknown (i.e., X), and floating (i.e., Z). As such, device gate column 601 is representative of a column which defines the current state of a device gate as off. Meaning that, the amount of voltage which flows through the device gate is equal to zero, or less than a threshold voltage. Similarly, device gate column 602 is also representative of a column which defines the state for a device gate of an associated transistor, such that device gate column 602 is representative of a column which defines the current state of a device gate as on. Meaning that, the amount of voltage which flows through the device gate is less than the threshold voltage.

Source terminal column 603 is representative of a column which describes the various states for the source terminal of an associated transistor. In an implementation, the source terminal of a transistor may be represented within four different states including, off (i.e., 0), on (i.e., VDD), unknown (i.e., X), and floating (i.e., Z). Similarly, drain terminal column 605 describes the various states for the drain terminal of an associated transistor, such that the states of the drain terminal also include, off (i.e., 0), on (i.e., VDD), unknown (i.e., X), and floating (i.e., Z).

PMOS gate voltage column 604 is representative of a column which indicates the current voltage between the device gate and source terminal of an associated PMOS. For example, PMOS gate voltage column 604 may indicate that the voltage between the device gate and the source terminal of the PMOS is a negative value which represents the difference in voltage between the voltage at the device gate and the voltage at the source terminal.

Alternatively, NMOS gate voltage column 606 is representative of a column which indicates the current voltage between the device gate and source terminal of an associated NMOS. For example, NMOS gate voltage column 606 may indicate that the voltage between the device gate and the source terminal is equal to a positive value which represents the difference in voltage between the voltage at the device gate and the voltage at the source terminal. Alternatively, NMOS gate voltage column 606 may indicate that the voltage between the device gate and the source terminal is equal to the input voltage (i.e., VDD).

Mode column 607 is representative of a column which provides an indication on if the mode of an associated transistor is open or connected. An open transistor is representative of a transistor which is not connected to other circuit elements. Alternatively, a connected transistor is representative of a transistor which is connected to other elements.

Output column 608 is representative of a column which indicates the directionality of a device gate, based on the conditions outlined by device gate column 601, device gate column 602, source terminal column 603, PMOS gate voltage column 604, drain terminal column 605, NMOS gate voltage column 606, and mode column 607. In an implementation, if the source terminal and the drain terminal of an associated transistor are within the same state, then output column 608 is configured to classify the directionality of the transistor as a bidirectional model. Alternatively, if the source terminal and the drain terminal of an associated transistor are not within the same state, then output column 608 is configured to classify the directionality of the transistor as a unidirectional model

In an implementation table 600 is utilized by circuitry configured to generate a netlist of an analog or mixed-signal circuit. For example, netlist generation engine 102 may utilize table 600 to generate netlist 103, such that netlist 103 describes the directionality of the device gates within analog circuit design 101.

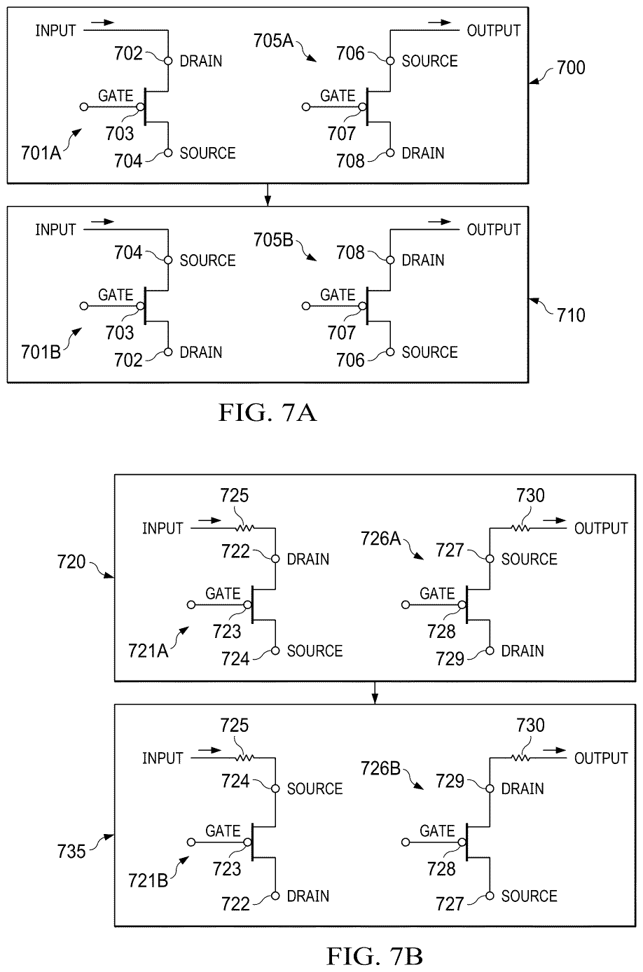

FIGS. 7A and 7B illustrate an operational scenario for reversing the polarity of a transistor (e.g., PMOS or NMOS) in an implementation. As such, FIGS. 7A and 7B illustrate a scenario for generating a netlist (e.g., netlist 103) of an analog or mixed-signal circuit. A netlist is representative of a text description of a circuit which describes the directionality of each transistor represented within the circuit as either a unidirectional model or a bidirectional model.

A unidirectional model is representative of a transistor model, where the source terminal or the drain terminal of the associated transistor is either directly or indirectly connected to an input node or an output node of the circuit. Alternatively, a bidirectional model is representative of a transistor model where neither the source terminal nor the drain terminal of the associated transistor is connected directly or indirectly to an input node or an output node of the circuit. As a result, the directionality of a transistor is determined based on the locations of the source terminal and the drain terminal of the transistor.

In an implementation, if it is determined that a transistor is representative of a unidirectional model, but the source terminal of the transistor is connected to an output node of the circuit, or the drain terminal of the transistor is connected to an input node of the circuit, then the circuitry which classified the transistor as a unidirectional model is further configured to reverse the polarity of the transistor. Meaning, the circuitry is configured to cause the source terminal of the transistor (rather than the drain terminal) to be connected to the input node, or cause the drain terminal of the transistor (rather than the source terminal) to be connected to the output node of the circuit. Advantageously, reversing the polarity of the transistor allows the circuitry to generate a netlist which may be supplied as input to an analysis engine (e.g., analysis engine 106) which is configured to leverage digital circuit analysis techniques for performing analog/mixed-signal circuit analysis.

Now turning to FIG. 7A, FIG. 7A illustrates a first scenario for reversing the polarity of a transistor. FIG. 7A includes stage 700 and stage 710. Stage 700 is representative of a stage for determining the locations of the source terminal and the drain terminal of an associated transistor. Stage 700 includes transistor 701A and transistor 705A.

Transistor 701A represents either an NMOS or PMOS from an analog/mixed-signal circuit, such that transistor 701A includes drain terminal 702, device gate 703, and source terminal 704. Similarly, transistor 705A also represents an NMOS or PMOS from an analog/mixed-signal circuit, such that transistor 705A includes source terminal 706, device gate 707, and drain terminal 708. For example, transistors 701A and 705A may represent transistors from analog circuit design 101.

In an implementation, circuitry configured to generate a netlist for an analog or mixed-signal circuit is configured to determine the directionality of transistors 701A and 705A based on the locations of the source terminals and drain terminals of each transistor. For example, the circuitry may determine that drain terminal 702 of transistor 701A is directly connected to an input node of the associated circuit, and as a result, classify transistor 701A as a unidirectional model. In addition, the circuitry may determine that source terminal 706 of transistor 705A is directly connected to an output node of the associated circuit, and as a result, classify transistor 705A as a unidirectional model. In an implementation, if the circuitry determines that a drain terminal of a transistor is connected to an input node, or that a source terminal of a transistor is connected to an output node, then the circuitry is configured to reverse the polarity of the transistor, as illustrated by stage 710.

Stage 710 is representative of a stage for reversing the polarity of transistors 701A and 705A. As such, stage 710 includes transistors 701B and 705B. Transistor 701B is representative of a unidirectional model where source terminal 704 is connected to the input node of the circuit (rather than drain terminal 702). Similarly, transistor 705B is representative of a unidirectional model where drain terminal 708 is connected to the output node of the circuit (rather than source terminal 706).

Now turning to FIG. 7B, FIG. 7B includes stage 720 and stage 735. Stage 720 is representative of another stage for determining the locations of the source terminal and the drain terminal of an associated transistor. Stage 720 includes transistor 721A, resistor 725, transistor 726A, and resistor 730.

Transistor 721A is representative of either an NMOS or PMOS from an analog/mixed-signal circuit, such that transistor 721A includes drain terminal 722, device gate 723, and source terminal 724. Similarly, transistor 726A is also representative of an NMOS or PMOS from an analog/mixed-signal circuit, such that transistor 726A includes source terminal 727, device gate 728, and drain terminal 729. In an implementation, circuitry configured to generate a netlist for an analog or mixed-signal circuit is configured to determine the directionality of transistors 721A and 726 based on the locations of the source and drain terminals of each transistor. For example, the circuitry may determine that drain terminal 722 of transistor 721A is connected to resistor 725, such that resistor 725 is connected to an input node of the associated circuit. Meaning, the circuitry may determine that drain terminal 722 is indirectly connected to an input node of the circuit, and as a result, classify transistor 721A as a unidirectional model.

In addition, the circuitry may determine that source terminal 727 of transistor 726A is connected to resistor 730, such that resistor 730 is connected to an output node of the associated circuit. Meaning, the circuitry may determine that source terminal 727 is indirectly connected to an output node of the circuit, and as a result, classify transistor 726A as a unidirectional model. In an implementation, if the circuitry determines that a drain terminal of a transistor is indirectly connected to an input node, or that a source terminal of a transistor is indirectly connected to an output node, then the circuitry is configured to reverse the polarity of the transistor, as illustrated by stage 735.

Stage 735 is representative of a stage for reversing the polarity of transistors 721A and 726A. As such, stage 735 includes transistors 721B and 726B. Transistor 721B is representative of a unidirectional model where source terminal 724 is connected to resistor 725 (rather than drain terminal 722), and in turn, the input node of the circuit. Similarly, transistor 726B is representative of a unidirectional model where drain terminal 729 is connected to resistor 730 (rather than source terminal 727), and in turn, to the output node of the circuit.

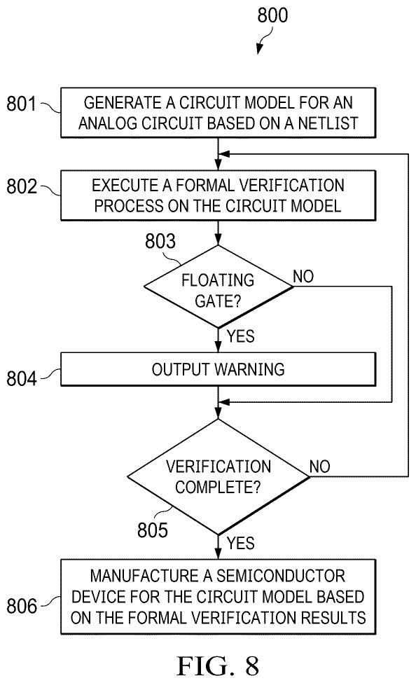

FIG. 8 illustrates analysis process 800 in an implementation. Analysis process 800 is representative of software for performing circuit analysis with respect to analog or mixed-signal circuits. For example, analysis process 800 may be representative of analysis method 200 of FIG. 2. Analysis process 800 may be implemented in the context of program instructions that, when executed by a suitable computing system, direct the processing circuitry of the computing system to operate as follows, referring parenthetically to the steps in FIG. 8. For the purposes of explanation, analysis process 800 will be explained with the elements of FIG. 1. This is not meant to limit the applications of analysis process 800, but rather to provide an example.

To begin, model generation engine 104 is configured to generate circuit model 105 based on netlist 103, and further based on analog circuit design 101 (step 801). Circuit model 105 is representative of a digital representation of an analog or mixed-signal circuit, such that circuit model 105 may be supplied to circuitry configured to leverage digital circuit analysis techniques for performing analog/mixed-signal circuit analysis. For example, model generation engine 104 may supply circuit model 105 to analysis engine 106, and in response, analysis engine 106 is configured to execute a formal verification process with respect to circuit model 105 (step 802).

The formal verification process is representative of a mathematical approach for ensuring the elements of circuit model 105 are behaving as expected under all possible conditions. In other words, the formal verification process is representative of an exhaustive technique for identifying the conditions which cause the device gates of circuit model 105 to be representative of floating gates. In an implementation, during the formal verification process, analysis engine 106 is configured to determine if certain conditions cause a device gate of circuit model 105 to be representative of a floating gate (step 803).

If analysis engine 106 determines that a certain set of conditions does not cause a floating gate, then analysis engine 106 is configured to determine if the formal verification process is complete (step 805). Alternatively, if analysis engine 106 determines that the certain set of conditions causes a floating gate, then analysis engine 106 is configured to output a warning which indicates the specific conditions that caused the floating gate (step 804) and determine if the formal verification process is complete (step 805).

If the formal verification process is not complete, then analysis engine continues executing the formal verification process by testing the elements of circuit model 105 under a new set of conditions. Alternatively, if the formal verification process is complete, then analysis engine 106 is configured to output analysis results 107, and supply analysis results 107 to circuitry configured to manufacture a semiconductor device for circuit model 105 based on analysis results 107 (step 806). For example, the circuitry may adjust circuit model 105 to mitigate the chances of floating gates within the manufactured semiconductor device.

Advantageously, analysis process 800 provides a technique for manufacturing an analog/mixed-signal circuit which mitigates the effects caused by floating gates within the manufactured circuit. Accordingly, analysis process 800 provides a technique which reduces the chances of current leakage, and in turn, data corruption, increased power consumption, and signal degradation within the manufactured circuit. In addition, analysis process 800 provides a technique which results in cost savings for the manufacturers/customers for when the circuit is deployed.

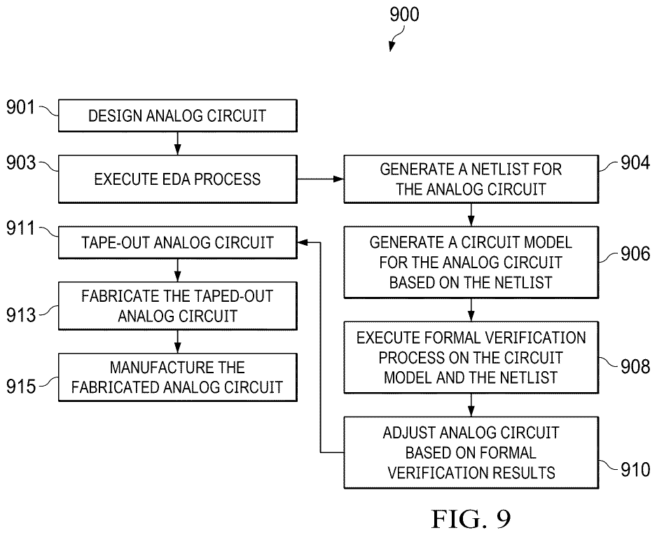

Now turning to the next figure, FIG. 9 illustrates analysis process 900 in an implementation. Analysis process 900 is representative of software for performing circuit analysis with respect to analog/mixed-signal circuits, and manufacturing a semiconductor device based on the results of the circuit analysis. For example, analysis process 900 may be representative of analysis process 800 of FIG. 8. Analysis process 900 may be implemented in the context of program instructions that, when executed by a suitable computing system, direct the processing circuitry of the computing system to operate as follows, referring parenthetically to the steps in FIG. 9. For the purposes of explanation, analysis process 900 will be explained with the elements of FIG. 1. This is not meant to limit the applications of analysis process 900, but rather to provide an example.

To begin, a user associated with operating environment 100 creates a design for an analog or mixed-signal circuit (step 901). For example, the user may generate analog circuit design 101. Next, the user supplies analog circuit design 101 to circuitry configured to execute electronic design automation (EDA) processes with respect to the user generated design (step 903). For example, the user may supply analog circuit design 101 to netlist generation engine 102 to cause netlist generation engine 102 to generate netlist 103 (step 904).

Next, the user may supply analog circuit design 101 to model generation engine 104 to cause model generation engine 104 to generate circuit model 105 for analog circuit design 101 based on netlist 103 (step 906). Once generated, model generation engine 104 is configured to supply circuit model 105, and netlist 103, to analysis engine 106 to cause analysis engine 106 to execute a formal verification process with respect to circuit model 105 and netlist 103 (step 908).

In an implementation, after executing the formal verification process, analysis engine 106 is configured to output analysis results 107 and adjust circuit model 105 based on analysis results 107 (step 910). For example, if analysis results 107 indicate the conditions which caused the device gates of circuit model 105 to be representative of floating gates, then analysis engine 106 may adjust circuit model 105, and in turn, analog circuit design 101, to mitigate the chances of floating gates for when the circuit is deployed. Once adjusted, analysis engine 106 may supply the adjusted circuit design to circuitry configured to manufacture a circuit based on the adjusted circuit design.

For example, analysis engine 106 may supply the updated circuit design to circuitry which is first configured to tape-out the design, and as a result, generate a photomask of said design (step 911). Next, the circuitry is configured to fabricate the photomask of the design to generate a physical copy of the updated circuit design (step 913). Once fabricated, the updated analog circuit design may be manufactured (step 915).

Advantageously, analysis process 900 provides a technique for manufacturing an analog/mixed-signal circuit which mitigates the chances of floating gates within the manufactured circuit. As a result, analysis process 900 provides a technique for manufacturing a circuit which increases the cost savings for the manufacturers/customers of the circuit by reducing the chances of current leakage for when the circuit is deployed.

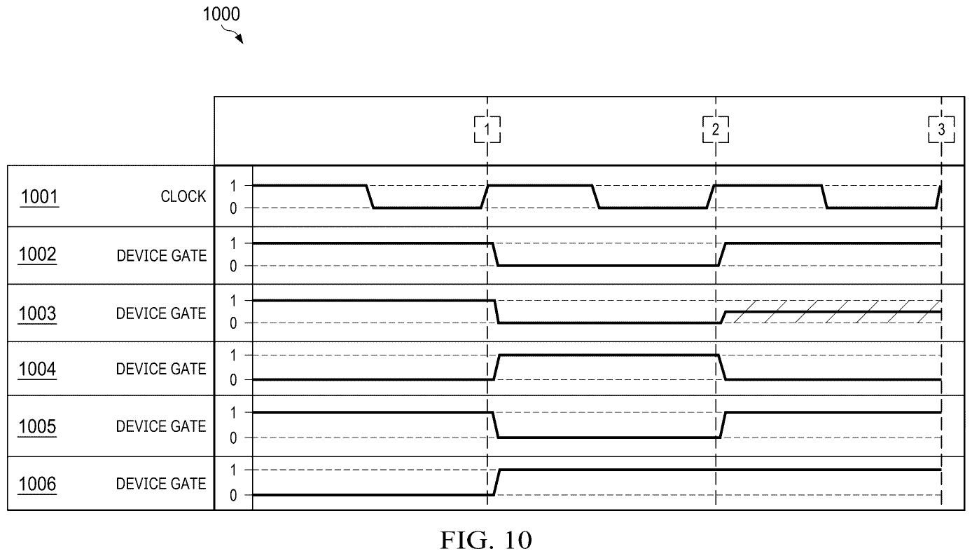

FIG. 10 illustrates table 1000 in an implementation. Table 1000 is representative of a table which displays the various states for the device gates of an analog or mixed-signal circuit. For example, table 1000 may illustrate the various states for the device gates of analog circuit 400. Table 1000 includes clock cycle row 1001, and device gate rows 1002, 1003, 1004, 1005, and 1006.

Clock cycle row 1001 is representative of a row which depicts the clock cycles of an associated circuit. For example, clock cycle row 1001 may depict three different clock cycles, such that in each cycle, the clock is represented within a high-logic level (i.e., 1), and a low-logic level (i.e., 0). In an implementation, the clock of the associated circuit designates the current state of the device gates, as depicted by device gate rows 1002, 1003, 1004, 1005, and 1006.

Device gate rows 1002-1006 are representative of rows which each depict the various states of an associated device gate, such that the various states include an on state (i.e., 1), an off state (i.e., 0), and an unknown state. For example, within the first clock cycle, device gate rows 1002, 1003, and 1005 indicate that the associated device gates are within the on state, while device gate rows 1004 and 1006 indicate that the associated device gates are within the off state. Alternatively, within the second clock cycle, device gate rows 1002, 1003, and 1005 indicate that the associated device gates are within the off state, while device gate rows 1004 and 1006 indicate that the associated device gates are within the on state.

In an implementation, the device gates of the transistors are configured to convert from the on state to the off state, and vice versa between each clock cycle. Problematically, when switching states, a device gate may switch to the unknown state. Meaning that, the device gate converts to a floating gate. For example, during the second clock cycle, device gate row 1003 depicts the associated device gate within the off state, but when converting to the third clock cycle, device gate row 1003 depicts the associated device gate within the unknown state. Accordingly, the device gate of device gate row 1003 is representative of a floating gate by the third clock cycle.

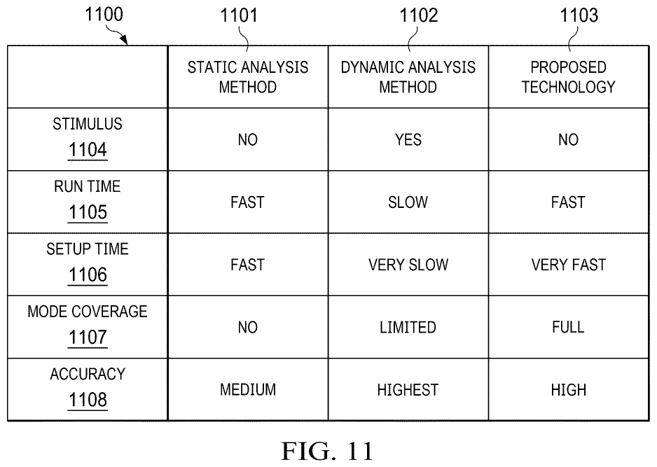

FIG. 11 illustrates results table 1100 in an implementation. Results table 1100 is representative of a table which compares the existing analog/mixed-signal circuit analysis techniques with the technology disclosed herein. Results table 1100 includes static analysis method column 1101, dynamic analysis method column 1102, proposed technology column 1103, stimulus row 1104, run time row 1105, setup time row 1106, mode coverage row 1107, and accuracy row 1108.

Static analysis method column 1101 is representative of a column which stores the data for the currently existing static analysis methodologies. Meaning that, static analysis method column 1101 stores the data for performing analog/mixed-signal circuit analysis via a topology check of the circuit where the various connections within the circuit are tested to ensure the elements are properly configured.

Alternatively, dynamic analysis method column 1102 is representative of a column which stores the data for the currently existing dynamic analysis methodologies. Meaning that, dynamic analysis method column 1102 stores the data for performing analog/mixed-signal circuit analysis via a transient simulation of the circuit where the transient simulation is tested under various conditions.

Proposed technology column 1103 is representative of a column which stores the data for the methodologies that are presented herein. Meaning that, proposed technology column 1103 stores the data for performing analog/mixed-signal circuit analysis via analysis method 200, analysis process 800, or analysis process 900. In an implementation, proposed technology column 1103 illustrates the advantages for performing circuit analysis with the techniques presented herein as compared to performing circuit analysis with the currently existing techniques. For example, stimulus row 1104 indicates that the current dynamic analysis methods require user provided stimulus while current static analysis methods and the proposed technology do not. As a result, the proposed technology provides an advantage over current dynamic analysis methods as the proposed technology does not require the user to have a complete understanding of the circuit to trigger conditions which create floating gates within the circuit.

Run time row 1105 is representative of a row which compares the run time for executing the various circuit analysis methods. As such, run time row 1105 indicates that current static analysis methods and the proposed technology provide fast techniques for performing circuit analysis, while current dynamic analysis methods provide a slow technique for performing circuit analysis. Meaning that, the proposed technology provides an advantage over the current dynamic analysis methods since the proposed technology provides a quicker approach for performing circuit analysis. The proposed technology may save time in the analysis and verification process by detecting floating gates upfront, early in the process.

Setup time row 1106 is representative of a row which compares the setup time for performing the various circuit analysis methodologies. As such, setup time row 1106 indicates that setting up the proposed technology techniques takes less time than setting up either the current static analysis methods or the current dynamic analysis methods. Accordingly, the proposed technology provides an advantage over both the current static and dynamic analysis methods as the proposed technology takes less time to set up.

Mode coverage row 1107 is representative of a row which compares the exhaustiveness of each technique. As such, mode coverage row 1107 indicates that the proposed technology provides a completely exhaustive approach for testing a circuit under all possible conditions, while the current static/dynamic analysis methods do not. As a result, the proposed technology provides a more reliable technique for detecting floating gates as the proposed technology tests the circuit under all possible conditions.

Accuracy row 1108 is representative of a row which compares the accuracy of each technique. As such, accuracy row 1108 indicates that the current dynamic analysis methods are the most accurate method, while the proposed technology provides a more accurate method than the current static analysis methods. It should be noted that, even though the current dynamic analysis methods are more accurate, the current dynamic analysis methods are non-exhaustive. Meaning that, the current dynamic analysis methods are unable to detect every scenario which may trigger a floating gate, while the proposed technology is able to detect every scenario which may trigger a floating gate.

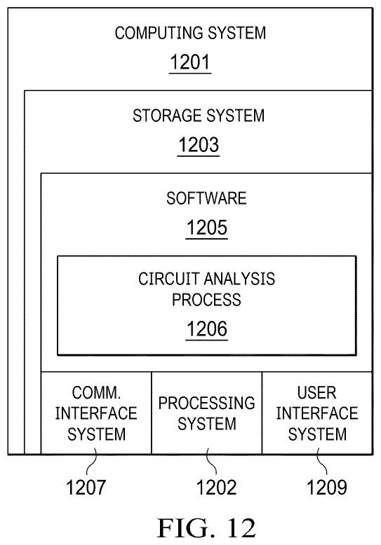

FIG. 12 illustrates an example computer system that may be used in various implementations. For example, computing system 1201 is representative of a computing device capable of performing analog/mixed-signal circuit analysis as described herein. Computing system 1201 is representative of any system or collection of systems with which the various operational architectures, processes, scenarios, and sequences disclosed herein for performing analog/mixed-signal circuit analysis may be employed. Examples of computing system 1201 include—but are not limited to—micro controller units (MCUs), embedded computing devices, server computers, cloud computers, personal computers, mobile phones, and the like.

Computing system 1201 may be implemented as a single apparatus, system, or device or may be implemented in a distributed manner as multiple apparatuses, systems, or devices. Computing system 1201 includes, but is not limited to, processing system 1202, storage system 1203, software 1205, communication interface system 1207, and user interface system 1209 (optional). Processing system 1202 is operatively coupled with storage system 1203, communication interface system 1207, and user interface system 1209. Computing system 1201 may be representative of a cloud computing device, distributed computing device, or the like.

Processing system 1202 loads and executes software 1205 from storage system 1203, or alternatively, runs software 1205 directly from storage system 1203. Software 1205 includes program instructions, which includes circuit analysis process 1206 (e.g., analysis method 200, analysis process 800, analysis process 900). When executed by processing system 1202, software 1205 directs processing system 1202 to operate as described herein for at least the various processes, operational scenarios, and sequences discussed in the foregoing implementations. Computing device 1201 may optionally include additional devices, features, or functions not discussed for purposes of brevity.

Referring still to FIG. 12, processing system 1202 may comprise a micro-processor and other circuitry that retrieves and executes software 1205 from storage system 1203. Processing system 1202 may be implemented within a single processing device but may also be distributed across multiple processing devices or sub-systems that cooperate in executing program instructions. Examples of processing system 1202 include general purpose central processing units, graphical processing units, digital signal processing units, data processing units, application specific processors, and logic devices, as well as any other type of processing device, combinations, or variations thereof.

Storage system 1203 may comprise any computer readable storage media readable and writeable by processing system 1202 and capable of storing software 1205. Storage system 1203 may include volatile and nonvolatile, removable and non-removable, mutable and non-mutable media implemented in any method or technology for storage of information, such as computer readable instructions, data structures, program modules, or other data. Examples of storage media include random access memory, read only memory, magnetic disks, optical disks, optical media, flash memory, virtual memory and non-virtual memory, magnetic cassettes, magnetic tape, magnetic disk storage or other magnetic storage devices, or any other suitable storage media. In no case is the computer readable storage media a propagated signal.

In addition to computer readable storage media, in some implementations storage system 1203 may also include computer readable communication media over which at least some of software 1205 may be communicated internally or externally. Storage system 1203 may be implemented as a single storage device but may also be implemented across multiple storage devices or sub-systems co-located or distributed relative to each other. Storage system 1203 may comprise additional elements, such as a controller, capable of communicating with processing system 1202 or possibly other systems.

Software 1205 may be implemented in program instructions and among other functions may, when executed by processing system 1202, direct processing system 1202 to operate as described with respect to the various operational scenarios, sequences, and processes illustrated herein. In particular, the program instructions may include various components or modules that cooperate or otherwise interact to carry out the various processes and operational scenarios described herein. The various components or modules may be embodied in compiled or interpreted instructions, or in some other variation or combination of instructions. The various components or modules may be executed in a synchronous or asynchronous manner, serially or in parallel, in a single threaded environment or multi-threaded, or in accordance with any other suitable execution paradigm, variation, or combination thereof. Software 1205 may include additional processes, programs, or components, such as operating system software, virtualization software, or other application software. Software 1205 may also comprise firmware or some other form of machine-readable processing instructions executable by processing system 1202.

In general, software 1205 may, when loaded into processing system 1202 and executed, transform a suitable apparatus, system, or device (of which computing device 1201 is representative) overall from a general-purpose computing system into a special-purpose computing system customized to support binary convolution operations. Indeed, encoding software 1205 (and circuit analysis process 1206) on storage system 1203 may transform the physical structure of storage system 1203. The specific transformation of the physical structure may depend on various factors in different implementations of this description. Examples of such factors may include, but are not limited to, the technology used to implement the storage media of storage system 1203 and whether the computer-storage media are characterized as primary or secondary, etc.

For example, if the computer readable storage media are implemented as semiconductor-based memory, software 1205 may transform the physical state of the semiconductor memory when the program instructions are encoded therein, such as by transforming the state of transistors, capacitors, or other discrete circuit elements constituting the semiconductor memory. A similar transformation may occur with respect to magnetic or optical media. Other transformations of physical media are possible without departing from the scope of the present description, with the foregoing examples provided only to facilitate the present discussion.

Communication interface system 1207 may include communication connections and devices that allow for communication with other computing systems (not shown) over communication networks (not shown). Examples of connections and devices that together allow for inter-system communication may include network interface cards, antennas, power amplifiers, radiofrequency circuitry, transceivers, and other communication circuitry. The connections and devices may communicate over communication media to exchange communications with other computing systems or networks of systems, such as metal, glass, air, or any other suitable communication media. The aforementioned media, connections, and devices are well known and need not be discussed at length here.

Communication between computing system 1201 and other computing systems (not shown), may occur over a communication network or networks and in accordance with various communication protocols, combinations of protocols, or variations thereof. Examples include intranets, internets, the Internet, local area networks, wide area networks, wireless networks, wired networks, virtual networks, software defined networks, data center buses and backplanes, or any other type of network, combination of networks, or variation thereof. The aforementioned communication networks and protocols are well known and need not be discussed at length here.

As will be appreciated by one skilled in the art, aspects of the present invention may be embodied as a system, method, or computer program product. Accordingly, aspects of the present invention may take the form of an entirely hardware implementation, an entirely software implementation (including firmware, resident software, micro-code, etc.) or an implementation combining software and hardware aspects that may all generally be referred to herein as a “circuit,” “module” or “system.” Furthermore, aspects of the present invention may take the form of a computer program product embodied in one or more computer readable medium(s) having computer readable program code embodied thereon.

Indeed, the included descriptions and figures depict specific implementations to teach those skilled in the art how to make and use the best mode. For the purpose of teaching inventive principles, some conventional aspects have been simplified or omitted. Those skilled in the art will appreciate variations from these implementations that fall within the scope of the disclosure. Those skilled in the art will also appreciate that the features described above may be combined in various ways to form multiple implementations. As a result, the invention is not limited to the specific implementations described above, but only by the claims and their equivalents.

The above description and associated figures teach the best mode of the invention. The following claims specify the scope of the invention. Note that some aspects of the best mode may not fall within the scope of the invention as specified by the claims. Those skilled in the art will appreciate that the features described above can be combined in various ways to form multiple variations of the invention. Thus, the invention is not limited to the specific embodiments described above, but only by the following claims and their equivalents.

What is claimed is:

1. A method for performing analog circuit analysis, the method comprising:
generating a netlist for one or more device gates of an analog circuit, wherein generating the netlist comprises, for each device gate of the one or more device gates:
determining a type for the device gate; and
determining a directionality for the device gate based on a logical position of a source terminal of the device gate and a logical position of a drain terminal of the device gate;
generating a circuit model for the analog circuit based on the netlist; and
supplying the circuit model and the netlist as input to an analysis engine configured to perform the analog circuit analysis.

2. The method of claim 1, wherein performing the analog circuit analysis comprises executing a formal verification process with respect to the circuit model.

3. The method of claim 2, wherein executing the formal verification process comprises outputting a warning when a floating gate is detected in the circuit model.

4. The method of claim 1,
wherein the type includes a p-channel metal-oxide-semiconductor or an n-type metal-oxide-semiconductor, and
wherein the directionality includes a unidirectional model or a bidirectional model.

5. The method of claim 4, wherein determining the directionality comprises:
determining that the logical position of the source terminal of the device gate is coupled to an input node; and
setting the directionality of the device gate to the unidirectional model in response to determining that the logical position of the source terminal is coupled to the input node.

6. The method of claim 4, wherein determining the directionality comprises:
determining that the logical position of the drain terminal of the device gate is coupled to an output node; and
setting the directionality of the device gate to the unidirectional model in response to determining that the logical position of the drain terminal is coupled to the output node.

7. The method of claim 4, wherein determining the directionality comprises:
determining that the logical position of the source terminal of the device gate is coupled to an output node;
reversing a connectivity of the device gate; and
setting the directionality of the device gate to the unidirectional model in response to reversing the connectivity of the device gate.

8. The method of claim 4, wherein determining the directionality comprises:
determining that the logical position of the drain terminal of the device gate is coupled to an input node;
reversing a connectivity of the device gate; and
setting the directionality of the device gate to the unidirectional model in response to reversing the connectivity of the device gate.

9. The method of claim 4, wherein determining the directionality comprises:
determining that the logical position of the source terminal of the device gate is not coupled to an input node or an output node;
determining that the logical position of the drain terminal of the device gate is not coupled to the input node or the output node; and
setting the directionality of the device gate to the bidirectional model in response to determining that the logical position of the source terminal and the logical position of the drain terminal is not coupled to the input node or the output node.

10. The method of claim 1, further comprising manufacturing a semiconductor device for the analog circuit based on results of the analog circuit analysis.

11. A non-transitory computer-readable medium having executable instructions stored thereon, configured to be executable by processing circuitry for causing the processing circuitry to generate a circuit model for performing analog circuit analysis, wherein to generate the circuit model, the instructions are executable by the processing circuitry for further causing the processing circuitry to:
generate a netlist for one or more device gates of an analog circuit, wherein to generate the netlist, the instructions are executable by the processing circuitry for causing the processing circuitry to, for each device gate of the one or more device gates:
determine a type for the device gate; and
determine a directionality for the device gate based on a logical position of a source terminal of the device gate and a logical position of a drain terminal of the device gate;
generate the circuit model for the analog circuit based on the netlist; and
supply the circuit model and the netlist as input to an analysis engine configured to perform the analog circuit analysis.

12. The non-transitory computer-readable medium of claim 11, wherein to perform the analog circuit analysis, the analysis engine is configured to:
execute a formal verification process with respect to the circuit model; and
output a warning when a floating gate is detected in the circuit model.

13. The non-transitory computer-readable medium of claim 11, wherein the type includes a p-channel metal-oxide-semiconductor or an n-type metal-oxide-semiconductor, and wherein the directionality includes a unidirectional model or a bidirectional model.

14. The non-transitory computer-readable medium of claim 13, wherein to determine the directionality, the instructions are executable by the processing circuitry for further causing the processing circuitry to:
determine that the logical position of the source terminal of the device gate is coupled to an input node; and
set the directionality of the device gate to the unidirectional model in response to determining that the logical position of the source terminal is coupled to the input node.

15. The non-transitory computer-readable medium of claim 13, wherein to determine the directionality, the instructions are executable by the processing circuitry for further causing the processing circuitry to:
determine that the logical position of the drain terminal of the device gate is coupled to an output node; and
set the directionality of the device gate to the unidirectional model in response to determining that the logical position of the drain terminal is coupled to the output node.

16. The non-transitory computer-readable medium of claim 13, wherein to determine the directionality, the instructions are executable by the processing circuitry for further causing the processing circuitry to:
determine that the logical position of the source terminal of the device gate is coupled to an output node;
reverse a connectivity of the device gate; and
set the directionality of the device gate to the unidirectional model in response to reversing the connectivity of the device gate.

17. The non-transitory computer-readable medium of claim 13, wherein to determine the directionality, the instructions are executable by the processing circuitry for further causing the processing circuitry to:
determine that the logical position of the drain terminal of the device gate is coupled to an input node;
reverse a connectivity of the device gate; and
set the directionality of the device gate to the unidirectional model in response to reversing the connectivity of the device gate.

18. The non-transitory computer-readable medium of claim 13, wherein to determine the directionality, the instructions are executable by the processing circuitry for further causing the processing circuitry to:
determine that the logical position of the source terminal of the device gate is not coupled to an input node or an output node;
determine that the logical position of the drain terminal of the device gate is not coupled to the input node or the output node; and
set the directionality of the device gate to the bidirectional model in response to determining that the logical position of the source terminal and the logical position of the drain terminal is not coupled to the input node or the output node.

19. The non-transitory computer-readable medium of claim 11, wherein the instructions are executable by the processing circuitry for further causing the processing circuitry to manufacture a semiconductor device for the analog circuit based on results of the analog circuit analysis.

20. A system comprising:
a memory; and
processing circuitry coupled to the memory and configured to generate a circuit model of an analog circuit for performing analog circuit analysis, wherein the analog circuit comprises one or more device gates, and wherein to generate the circuit model the processing circuitry is configured to at least:
generate a netlist for one or more device gates of the analog circuit, wherein to generate the netlist, the processing circuitry is configured to, for each device gate of the one or more device gates:
determine a type for the device gate; and
determine a directionality for the device gate based on a logical position of a source terminal of the device gate and a logical position of a drain terminal of the device gate;
store the netlist to the memory;
generate the circuit model for the analog circuit based on the netlist; and
supply the circuit model and the netlist as input to an analysis engine configured to perform the analog circuit analysis.
